(19) United States
(12) Patent Application Publication
(10) Pub. No.: US 2012/0263203 A1
(43) Pub. Date: Oct. 18, 2012

(54) SEMICONDUCTOR LASER MODULE AND MANUFACTURING METHOD THEREOF

(75) Inventor: Naoki KOBAYASHI, Tokyo (JP)

(73) Assignee: NEC CORPORATION, Tokyo (JP)

(21) Appl. No.: 13/421,895

(22) Filed: Mar. 16, 2012

(30) Foreign Application Priority Data
Apr. 14, 2011 (JP) 2011-090342

(51) Int. Cl. H01S 5/02; H01L 33/48

(52) U.S. Cl. 372/44.01; 438/26; 257/E33.056

(57) ABSTRACT

To reduce the stress imposed on an LD chip and to sufficiently secure the heat radiation property of the LD chip. An LD module includes a PLC board, an LD chip, and a solder bump. The PLC board includes a PLC electrode. The LD chip includes an LD electrode, and a stripe-form active layer formed in an inner part adjacent to the LD electrode. The solder bump bonds the PLC electrode and the LD electrode by being disposed only in a part right under the active layer.

### CROSS-REFERENCE TO RELATED APPLICATION

This application is based upon and claims the benefit of priority from Japanese patent application No. 2011-090342, filed on Apr. 14, 2011, the disclosure of which is incorporated herein in its entirety by reference.

### BACKGROUND OF THE INVENTION

1. Field of the Invention

The present invention relates to a semiconductor laser module used for optical communications and the like, and to a manufacturing method thereof.

2. Description of the Related Art

There is a tremendous growth observed in optical communication systems in accordance with developments in recent technologies. In particular, technologies such as high-speed of optical signals and wavelength multiplexing thereof are being advanced in order to increase the use efficiency of fibers. In accordance with the developments in the technologies, requirements for the components used in the optical communication systems are becoming more demanding every year.

In the meantime, in accordance with developments in FTTH (Fiber To The Home), reduction in the cost of the used components has become an important issue. Recently, there is an increase in a demand for increasing the speed in FTTH. For example, the transmission speed is used to be about 100 Mbps in the beginning. Recently, however, those with the transmission speed of 2.4 Gbps are introduced on the market. Further, those with the transmission speed of 10 Gbps are to be on the market as well.

As described above, it is essential to employ a laser diode (referred to as “LD” herein after) that oscillates in a single mode under a condition where a communication capacity of several Gbps is required. In general, DFB (Distributed Feedback)-LD is used. In order to couple signals emitted from the DFB-LD to an optical fiber efficiently, position alignment of sub-micron level is required. The number of steps required for the alignment is a large issue in terms of reducing the cost. As a means for overcoming such issue, there is a method which mounts an LD on a planar lightwave circuit (referred to as “PLC” hereinafter) by passive alignment (Japanese Unexamined Patent Publication Hei 09-304663 (Patent Document 1)). With this method, it is unnecessary to spend the time for the alignment, so that a great reduction in the cost can be achieved.

Japanese Unexamined Patent Publication Hei 09-304663 (Patent Document 1), Japanese Unexamined Patent Publication 2003-023200 (Patent Documents 2), Japanese Unexamined Patent Publication 2009-212176 (Patent Documents 3), Japanese Unexamined Patent Publication Hei 07-072352 (Patent Documents 4), and Japanese Unexamined Patent Publication Hei 11-233877 (Patent Documents 5) disclose an LD module which includes a substrate, an LD chip, and a solder bump for bonding the substrate and the LD chip. In FIG. 1 and paragraph 0013 of Patent Document 1, it is depicted that a solder bump is provided in the center of an LD chip. However, there is no mention of the relation regarding the width of the solder bump and the width of an active layer of the LD chip. In FIG. 1 and FIG. 7 of Patent Document 2, a solder bump is spread almost on the entire surface of an LD chip. In paragraph 0028 of Patent Document 3, it is depicted to spread a solder in an area as wide as possible. In FIG. 2 of Patent Document 4, a solder bump is substantially spread almost on the entire surface through providing the solder bump in the center and four corners of an LD chip. In FIG. 6 and paragraphs 0003 to 0005 of Patent Document 5, it is depicted to process a soldering electrode to a stripe form. However, there is no mention of the relation regarding the width of the solder bump and the width of the active layer of the LD chip. The “width” in this Specification is defined as will be described later.

Hereinafter, it is to be noted that “LD” mainly means “DFB-LD”. It is an advantage of an LD module in which an LD chip is mounted on a PLC board that it can be manufactured at a low cost. In the meantime, such LD module has a disadvantage that a sub-mode suppression ratio (referred to as “SMSR” hereinafter) easily changes. This is because the LD chip that is sensitive to stress is mounted on a PLC board by solder bonding. That is, the stress is applied to the active layer of LD by the solder bonding, so that the oscillation state of the LD becomes unstable. This results in deterioration of the SMSR.

An LD chip mounting method according to the related technique is as follows. First, a solder bump is formed on the electrode on the PLC board. Subsequently, an LD chip is placed on the solder bump by facing the surface having the active layer towards the solder bump side. At last, heat is applied to the PLC board to melt the solder and it is cooled after being melted, thereby completing an LD module. Because of the solder bonding, the active layer of the LD comes under a stress that is caused due to thermal contraction of the solder.

As a technique for reducing the stress applied on the active layer, there is a technique with which no electrode is formed in the periphery under the active layer of the LD chip (Patent Document 3). With this technique, the LD chip surface and the solder are not alloyed in the part of the LD chip where the electrode is not formed, so that the stress imposed on the LD chip can be decreased. However, with this technique, deterioration of the property is generated in an optical surface due to a temperature increase caused according to the LD action even if the stress imposed on the LD chip can be decreased. This is because of the following reason. That is, the solder-bonding area right under the active layer becomes small and the waste heat path of the heat generated from the LD becomes narrow, so that the heat radiation property of the LD chip is deteriorated. Since the heat radiation property is poor, the heat generated from the LD persists in the periphery of the LD. This increase the inside temperature of the LD, and deteriorates the light output. The LD has such a characteristic that the light output is weakened as the temperature increases, so that it is strongly desired that the heat radiation property in the periphery of the LD is fine.

As described above, it is a critical point in mounting the LD to reduce the stress imposed on the LD chip and to sufficiently secure the heat radiation property of the LD chip. It is therefore an exemplary object of the present invention to provide an LD module that satisfies the two above-described points simultaneously and to provide a manufacturing method thereof.

### SUMMARY OF THE INVENTION

A semiconductor laser module according to an exemplary aspect of the invention is characterized to include: a substrate having a substrate-side electrode; a semiconductor laser chip having a chip-side electrode, and a stripe-form active layer formed in an inner part adjacent to the chip-side electrode; and a solder bump for bonding the substrate-side electrode and the chip-side electrode by being placed only in a part right under the active layer.

A semiconductor laser module manufacturing method according to another exemplary aspect of the invention is a method for manufacturing the semiconductor laser module according to the present invention, and the method is characterized to include: placing the solder bump on the substrate-side electrode of the substrate; placing the semiconductor laser chip on the solder bump by facing the chip-side electrode towards the solder bump; and bonding the substrate-side electrode and the chip-side electrode through heating and melting the solder bump.

### BRIEF DESCRIPTION OF THE DRAWINGS

FIGS. 1A and 1B show perspective views of a first exemplary embodiment of an LD module according to the present invention, in which FIG. 1A shows a state after an LD chip is mounted and FIG. 1B shows a state before the LD chip is mounted;

FIG. 2 is a detailed perspective view showing the LD module of FIG. 1A;

FIG. 3 is a fragmentary enlarged elevational view showing the LD module of FIG. 1A;

FIGS. 4A and 4B show perspective views of a second exemplary embodiment of the LD module according to the present invention, in which FIG. 4A shows a state after an LD chip is mounted and FIG. 4B shows a state before the LD chip is mounted;

FIG. 5 is a detailed perspective view showing the LD module of FIG. 4A;

FIGS. 6A to 6C show schematic elevational views for describing the effect of the LD module shown in FIG. 4A, in which FIG. 6A shows a state immediately after melting a solder according to a comparative example, FIG. 6B shows a state after solidifying the solder according to the comparative example, and FIG. 6C shows a state after solidifying a solder according to the second exemplary embodiment;

FIGS. 7A to 7C show perspective views of a third exemplary embodiment of the LD module according to the present invention before an LD chip is mounted, in which FIG. 7A shows a first example, FIG. 7C shows a second example, and FIG. 7C shows a third example; and

FIG. 8 is a perspective view of the third exemplary embodiment of the LD module according to the present invention before an LD chip is mounted, which shows a fourth example.

### DETAILED DESCRIPTION OF THE PREFERRED EMBODIMENTS

Hereinafter, modes for embodying the present invention (referred to as exemplary embodiments hereinafter) will be described by referring to the accompanying drawings. Further, those shown in the drawings may be illustrated larger than the actual sizes, the expansion rates thereof may be different for each part, and a part thereof may be omitted or simplified in order to implement easy understanding. In this Specification and the drawings, same reference numerals are used for substantially the same structural components.

Note that “PLC electrode”, “PLC board”, “LD electrode”, “LD chip”, and LD module” in the exemplary embodiments below correspond to respective examples of “substrate-side electrode”, “substrate”, “chip-side electrode”, “semiconductor laser chip”, and “semiconductor laser module” within the scope of the appended claims.

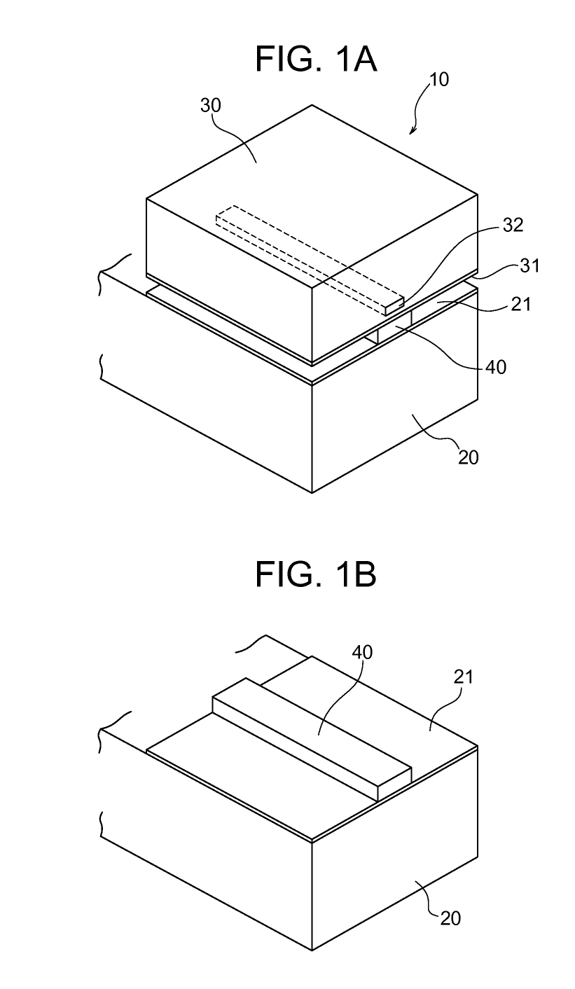

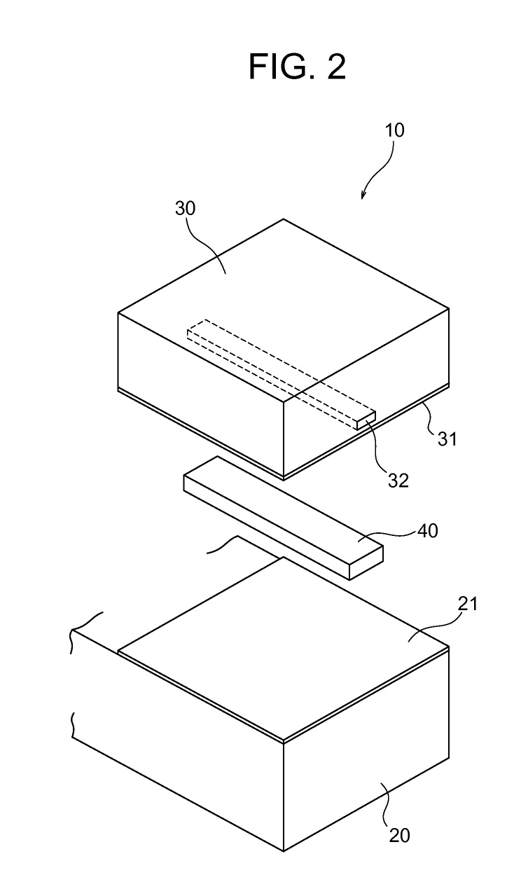

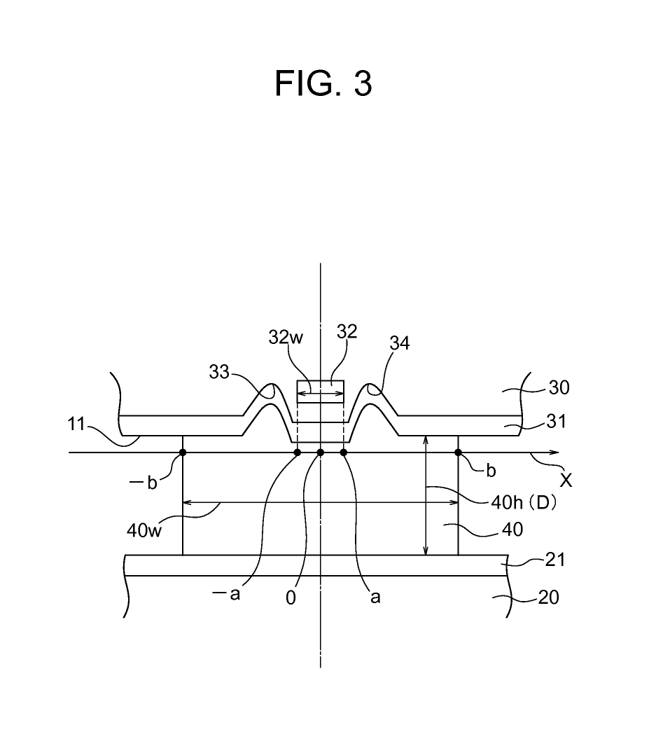

FIGS. 1A and 1B show perspective views of a first exemplary embodiment of an LD module according to the present invention, in which FIG. 1A shows a state after an LD chip is mounted and FIG. 1B shows a state before the LD chip is mounted. FIG. 2 is a detailed perspective view showing the LD module of FIG. 1A, and FIG. 3 is a fragmentary enlarged elevational view showing the LD module of FIG. 1A. Explanations will be provided hereinafter by referring to those drawings.

As shown in FIG. 1 and FIG. 2, an LD module 10 of a first exemplary embodiment includes a PLC board 20, an LD chip 30, and a solder bump 40. The PLC board 20 includes a PLC electrode 21. The LD chip 30 includes an LD electrode 31, and a stripe-form active layer 32 formed in an inner part adjacent to the LD electrode 31. The solder bump 40 bonds the PLC electrode 21 and the LD electrode 31, and it is disposed only in a part right under the active layer 32. Note here that “right under the active layer 32” means a part right under when the active layer 32 is disposed thereabove, and also conceptually means a part right above when the active layer 32 is placed thereunder.

For example, as shown in FIG. 3, width 40w of the solder bump 40 is 100 μm or less at the maximum provided that the size in the direction orthogonal to the extending direction of the active layer 32 in a surface 11 at which the LD electrode 31 and the solder bump 40 contact with each other is the width.

More specifically, following expressing [1] applies provided that the direction orthogonal to the extending direction of the active layer 32 in the surface 11 at which the LD electrode 31 and the solder bump 40 contact with each other is X-axis, the size on the X-axis is the width, the center of width 32w of the active layer 32 is the origin O of the X-axis, the coordinate of the width 32w of the active layer 32 on the X-axis is ±a, and the coordinate of the width 40w of the solder bump 40 on the X-axis is ±b

|2a|≦|2b|100 [μm] (1)

In FIG. 3, grooves 33 and 34 called mesas are formed in both sides of the active layer 32 along the extending direction of the active layer 32. The grooves 33 and 34 are omitted in other drawings. The width 32w of the active layer 32 is about 5 μm, for example. The solder bump 40 is in a cuboid shape, height 40h thereof is about 10 μm, for example, and the length (the depth direction) thereof is about 200 to 500 μm, for example. Further, while the PLC electrode 21 and the LD electrode 31 are formed almost on the entire part of one surface, those may also be formed in a specific shape without question.

Next, a manufacturing method of the LD module 10 will be described.

First, the solder bump 40 is placed on the PLC electrode 21 of the PLC board 20 (FIG. 1B). Subsequently, the LD chip 30 is placed on the solder bump 40 by facing the LD electrode 31 towards the solder bump 40 (FIG. 1A). At last, the solder bump 40 is heated and melted to bond the PLC electrode 21 and the LD electrode 31 (FIG. 1A).

When heating and melting the solder bump 40, it is preferable to fix the PLC board 20 and the LD chip 30 so that distance D between the PLC electrode 21 and the LD electrode 31 becomes a value defined in advance. Further, the solder bump 40 is heated for a short time at a temperature slightly over the melting point of the solder bump 40. Thereby, the shape of the melted and solidified solder bump 40 almost keeps the shape of the solder bump 40 that is before being melted.

Next, the effect of the LD module 10 will be described.

Since the solder bump 40 is placed only in the part right under the active layer 32, the stress imposed on the LD chip 30 caused due to the thermal contraction of the solder bump 40 can be decreased compared to that of the related technique in which the solder bump is disposed in a wider range of the LD chip. In addition, the solder bump 40 exists in the part right under the active layer 32, so that the heat radiation property of the LD chip 30 is not deteriorated.

In particular, by setting the width 40w of the solder bump 40 to be 100 μm or less at the maximum, the stress imposed on the LD chip 30 can be decreased more sufficiently. Further, by defining as “|2a|<|2b|” in Expression [1] described above, the heat radiation property of the LD chip 30 can be maintained more securely.

As an exemplary advantage according to the invention, it is possible to decrease the stress imposed on the semiconductor laser chip and to sufficiently secure the heat radiation property of the semiconductor laser chip by placing the solder bump only in the part right under the active layer of the semiconductor laser chip.

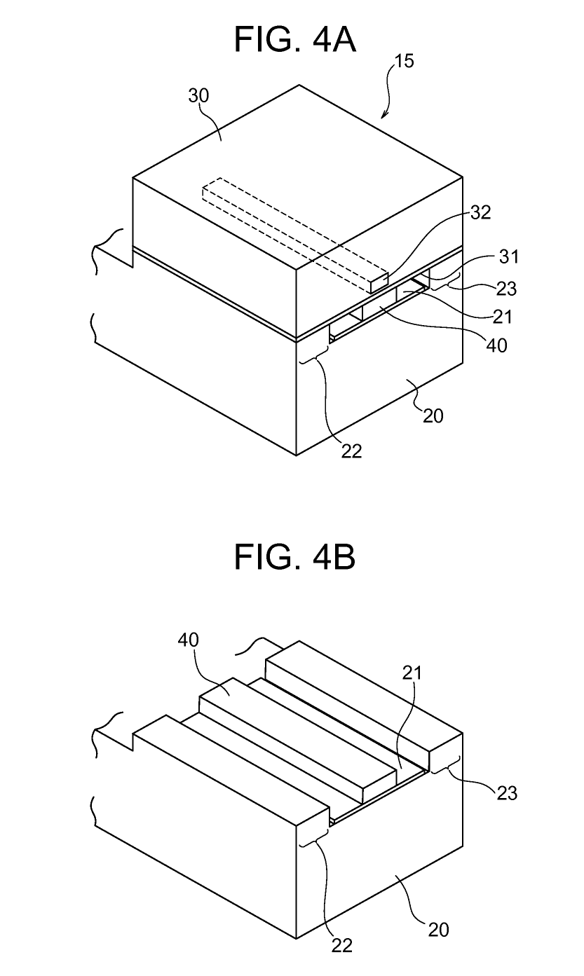

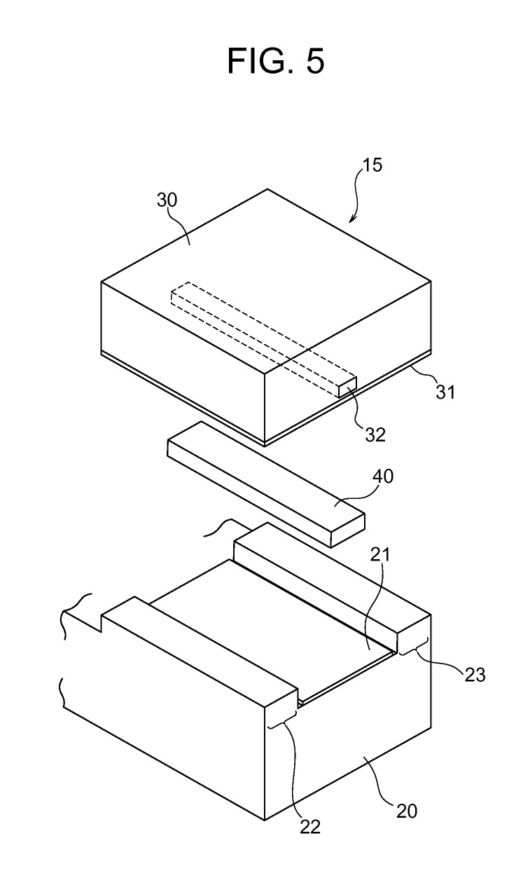

FIGS. 4A and 4B show perspective views of a second exemplary embodiment of the LD module according to the present invention, in which FIG. 4A shows a state after an LD chip is mounted and FIG. 4B shows a state before the LD chip is mounted. FIG. 5 is a detailed perspective view showing the LD module of FIG. 4A. Hereinafter, explanations will be provided by referring to those drawings. In FIGS. 4A, 4B and FIG. 5, same reference numerals are applied to the components that are the same as those of FIG. 1 and FIG. 2.

An LD module 15 of the second exemplary embodiment is different from the LD module of the first exemplary embodiment in respect that the PLC board 20 includes pedestals 22 and 23. The pedestals 22 and 23 set the height 40h of the solder bump 40 (FIG. 3) corresponding to the distance D (FIG. 3) between the PLC electrode 21 and the LD electrode 31 as a value defined in advance. Further, the positions where the pedestals 22 and 23 are formed in the PLC board 20 are positions where the both ends of the LD chip 30 are in contact. The both ends are the both ends along the direction that is orthogonal to the extending direction of the active layer 32.

The pedestals 22 and 23 are formed by etching the PLC board 20, for example. While the pedestals 22 and 23 are provided in the PLC board 20 in the second exemplary embodiment, those may be provided in the LD chip 30 or may be provided both in the PLC board 20 and the LD chip 30. The pedestals 22, 23 and the LD chip 30 are simply in contact with each other but not bonded or joined to each other by an adhesive.

Next, a manufacturing method of the LD module 15 will be described.

First, the solder bump 40 is placed on the PLC electrode 21 of the PLC board 20 (FIG. 4B). Subsequently, the LD chip 30 is placed on the solder bump 40 and the pedestals 22, 23 by facing the LD electrode 31 towards the solder bump 40 (FIG. 4A). At last, the solder bump 40 is heated and melted to bond the PLC electrode 21 and the LD electrode 31 (FIG. 4A). Next, the effect of the LD module 15 will be described.

With the LD module 15 of the second embodiment, it is possible to acquire the distance D (FIG. 3) between the PLC electrode 21 and the LD electrode 31 accurately and easily in addition to achieving the effect of the LD module of the first exemplary embodiment, since the PLC board 20 includes the pedestals 22 and 23.

Other structures, functions, and effects of the LD module 15 of the second exemplary embodiment are the same as those of the LD module of the first exemplary embodiment.

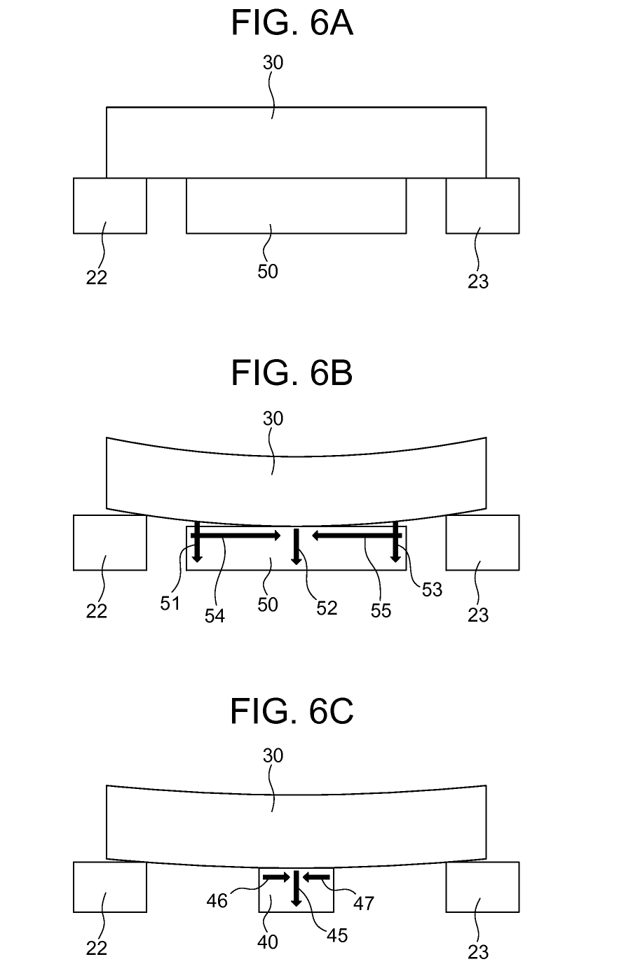

FIGS. 6A to 6C show schematic elevational views for describing the effect of the LD module 15, in which FIG. 6A shows a state immediately after melting the solder according to a comparative example, FIG. 6B shows a state after solidifying the solder according to the comparative example, and FIG. 6C shows a state after solidifying the solder according to the second exemplary embodiment. Hereinafter, the effect of the LD module 15 will be described in more details by referring to FIG. 4A to FIG. 6C.

In the second exemplary embodiment, reduction of the stress imposed on the LD chip 30 and the sufficient heat radiation property are achieved by devising the size and layout position of the solder bump 40. Details thereof will be described hereinafter. In a part right under the active layer 32 of the LD chip 30, the solder bump 40 in a size with which only the part right under the active layer 32 gets entirely wet after the solder is melted is disposed along the light oscillation direction (FIG. 4B). At this time, through using the amount of the solder with which only the part right under the active layer 32 gets wet after the solder is melted, the stress imposed on the LD chip 30 from the part other than the part right under the active layer 32 can be decreased. Further, through wetting only the part right under the active layer 32 as the heat generating source with solder entirely, it is possible to mount the LD chip 30 without deteriorating the heat radiation property.

The PLC electrode 21 and the pedestals 22, 23 for loading the LD chip are formed on the PLC board 20 (FIG. 5). Then, the solder bump 40 is formed on the PLC electrode 21 (FIG. 4B). For example, a large plate-type solder is punched out into the shape of the solder bump 40, and the solder bump 40 is placed on the PLC electrode 21 at the same time. After forming the solder bump 40, the LD chip 30 is placed on the pedestals 22, 23 by facing the surface having the active layer 32 towards the PLC electrode 21 side, and the solder bump 40 is melted by applying heat to the PLC board 20 (FIG. 4A). By the solder bonding, the active layer 32 of the LD chip 30 comes to have the stress caused due to the thermal contraction of the solder bump 40. Next, the reason for generating the stress will be described in a simple manner.

The thermal expansion coefficient of the solder bump 40 is larger than the thermal expansion coefficient of the PLC board 20. For example, the thermal expansion coefficient of AuSn (gold tin), as an example of the solder bump 40, is 17.5×10⁻⁶/° C., the thermal expansion coefficient of Si (silicon) as the main material of the PLC board 20 is 2.4×10⁻⁶/° C., and the thermal expansion coefficient of InP (indium phosphor) as the main material of the LD chip 30 is 4.5×10⁻⁶/° C. Thus, when the solder bump 40 and the PLC board 20 are cooled to the room temperature after mounting the LD chip 30, the solder bump 40 is contracted more than the PLC board 20.

As a result, as shown in FIG. 6C, a stress 45 for pulling the LD chip 30 to the PLC board side is generated. Further, the solder bump 40 is contracted greater than the PLC board, so that stresses 46, 47 for pulling the LD chip 30 towards the center of the solder bump 40 are generated. The stresses 45 to 47 change the refraction index of the active layer of the LD chip 30, unstabilize the oscillation state of the LD, and cause the deterioration of the SMSR property. Therefore, it is necessary to decrease the stress imposed on the LD chip 30 in order to improve the SMSR property.

In the meantime, in the comparative example shown in FIG. 6A and FIG. 6B, used is a solder bump 50 which is spread in a most part of one surface of the LD chip 30. Thus, stresses 51, 52, 53 of the comparative example for pulling the LD chip 30 towards the PLC board side and stresses 54, 55 for pulling the LD chip 30 towards the center of the solder bump 50 (FIG. 6B) are considerably larger than the stresses 45 to 47 (FIG. 6C) of the second exemplary embodiment. In other words, the second exemplary embodiment makes it possible to reduce the stress imposed on the LD chip 30 more greatly than the comparative example. While the effect of the second exemplary embodiment has been described in details heretofore, the effect of the first exemplary embodiment is also the same.

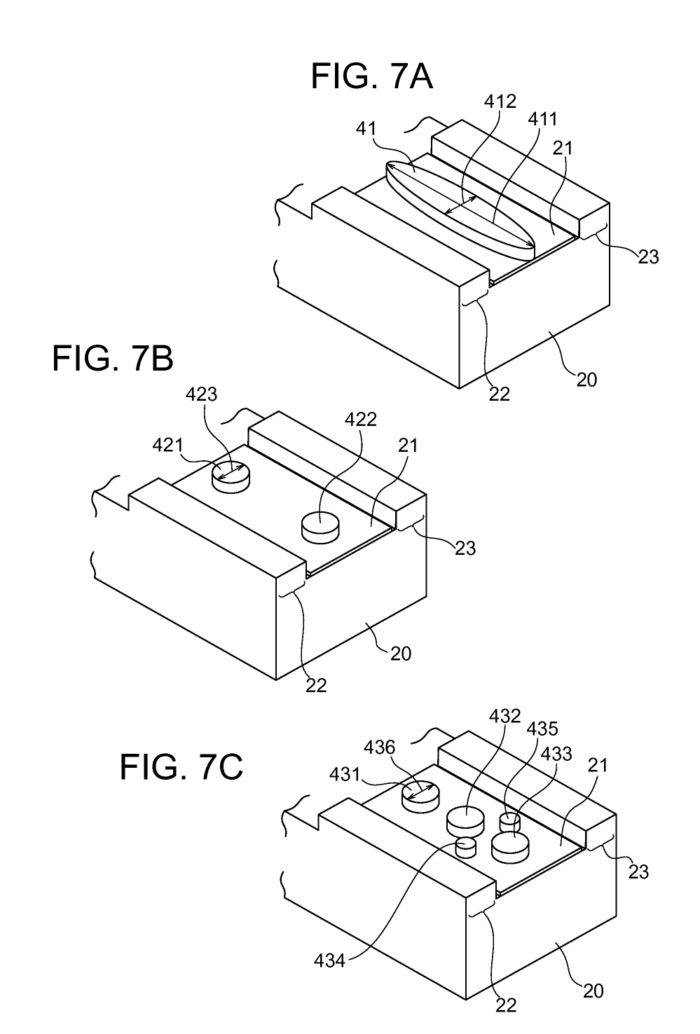

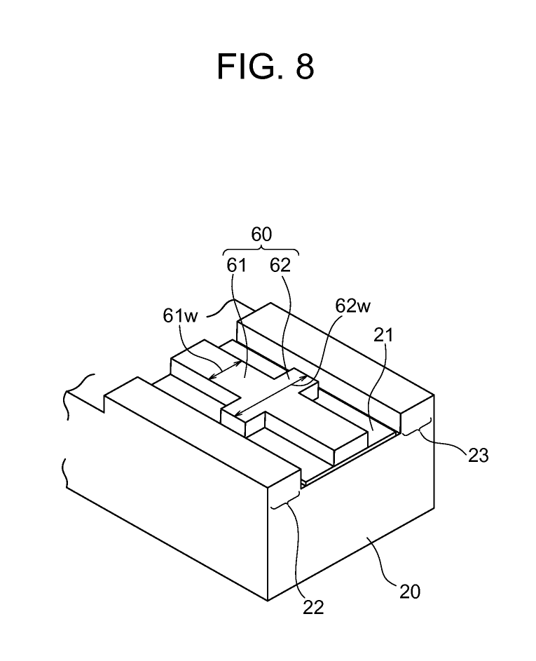

FIGS. 7A to 7C and FIG. 8 show perspective views of a third exemplary embodiment of the LD module according to the present invention before an LD chip is mounted, in which FIG. 7A shows a first example, FIG. 7C shows a second example, FIG. 7C shows a third example, and FIG. 8 shows a fourth example. In FIGS. 7A to 7C and FIG. 8, same reference numerals are applied to the components that are the same as those of FIGS. 4A, 4B and FIG. 5. Hereinafter, explanations will be provided by referring to those drawings.

In the first example shown in FIG. 7A, a solder bump 41 is in a flat cylindroid shape. It is disposed in such a manner that a major axis 411 of the solder bump 41 becomes the extending direction of the active layer. The width of the solder bum 41, i.e., a minor axis 412, is preferable to be 100 μm or less because of the reason described above. The solder bump 41 is formed in a flat cylindroid shape, so that a following effect can be achieved with the first example. In the LD chip, heat becomes more likely to persist as it gets closer to the center. Thus, by thickening the center of the solder bump 41 located in the center of the LD chip, the heat radiation property of the LD chip can be maintained in a fine manner. In addition, by thinning the both ends of the solder bump 41, the stress imposed upon the LD chip can be decreased further.

In the second example shown in FIG. 7B, solder bumps 421 and 422 are formed in a flat round columnar shape. The width of the solder bums 421 and 422, i.e., a diameter 423, is preferable to be 100 μm or less because of the reason described above. The solder bumps 421 and 422 are formed in a flat round columnar shape, so that a following effect can be achieved with the second example. It is unnecessary to mind the facing direction of the solder bumps 421 and 422, so that the workability when forming the solder bums 421 and 422 on the PLC electrode 21 can be improved.

In the third example shown in FIG. 7C, there are three flat round columnar shape solder bumps 431, 432, and 433. The width of the solder bums 431 to 433, i.e., a diameter 436, is preferable to be 100 μm or less because of the reason described above. In addition, the third example further includes solder bumps 434 and 435 (second solder bumps). The solder bumps 434 and 435 bond the PLC electrode 21 and the LD electrode, and are disposed between the solder bumps 431, 432, 433 (first solder bumps) and the fringe of the LD chip. As described above, in FIG. 2 of Patent Document 4, the solder bumps are substantially spread almost on the entire surface by providing the solder bumps in the center and the four corners (i.e., the fringe of the LD chip). In the meantime, with the third example, the solder bumps 434 and 435 are disposed not in the fringe of the LD chip but between the solder bums 431, 432, 433 and the fringe of the LD chip. Therefore, the stress can be decreased compared to the case of the related technique of Patent Document 4.

In the fourth example shown in FIG. 8, a solder bump 60 includes a main body 61 whose width 61w is 100 μm or less at the maximum and a projection part 42 whose width 42w is over 100 μm. It is so defined that he shape of the projection part 42 herein is a cuboid shape, the number thereof provided herein is two (a pair), and placed position thereof is substantially the center of the main body 61. However, there is no specific limit set for those. Further, while the main body 61 is defined herein as a cuboid shape, it can be formed in any shapes such as a cylindroid shape or a round columnar shape.

Regarding the round columnar solder bumps, four or more of those may be used. In the third exemplary embodiment, the shape of the solder bumps is almost the same before and after mounting the LD chip as in the cases of the first and second exemplary embodiment. Other structures, functions, and effects of the LD module of the third exemplary embodiment are the same as the LD modules of the first and second exemplary embodiments.

Further, in a case where it is desired to avoid the stress imposed upon a specific part of the LD chip, for example, the solder bump may be disposed at the specific part in such a manner that the solder does not get wet as in the cases of the second example and the third example (FIG. 7B, FIG. 7C). The shape, size, and number of the solder bump may be determined to satisfy the desired stress reduction effect and the heat radiation property. Thus, it is not necessarily required to have the solder wet on the entire surface right under the active layer.

In each of the exemplary embodiments described above, AuSn that is used often in general is assumed as the material for the solder. However, any other materials may be used, and a plurality of kinds of materials with different compositions may be used as well. “Different compositions” includes those under different element names and those under same element names with different composition ratios. It is assumed that light from the LD mounted on the PLC board makes incident on a waveguide on the PLC board. However, the emitted light may not need to make incident on the waveguide but may be coupled onto a lens, for example. In each of the exemplary embodiments, reduction of the stress includes reduction of the nonuniformity in the stress. When the stress imposed upon the active layer varies greatly depending on the positions of the active layer, the changes in the refractive index within the active layer vary depending on the positions of the active layer. Thus, the refractive index of the active layer becomes nonuniform, thereby deteriorating the SMSR property. Therefore, reduction of the nonuniformity in the stress is also important. In many cases, nonuniformity of the stress imposed upon the active layer can be reduced if the stress imposed upon the active layer can be reduced. The shapes of the solder bumps are expressed as “cuboid shape”, “cylindroid shape”, and “round columnar shape” in this Specification, and each of the surfaces is illustrated to cross each other at an acute angle in each drawing for implementing easy understanding. However, each of those surfaces actually cross with each other with rounded sides (so-called chamfered state), and it is to be noted that “cuboid shape”, “cylindroid shape”, and “round columnar shape” include those chamfered-state shapes.

In other words, the present invention is characterized to place and mount the solder in such a manner that only the part right under the active layer gets wet with a sufficient solder, when soldering and mounting the semiconductor laser chip to the substrate. That is, through disposing the solder only in a part right under the active layer in such a manner that the solder gets wet sufficiently, it becomes possible to reduce the stress imposed upon the LD and to acquire the sufficient heat radiation property.

While the present invention has been described above by referring to each of the exemplary embodiments, the present invention is not limited only to each of those exemplary embodiments. Various changes and modifications occurred to those skilled in the art can be applied to the structures and details of the present invention. Further, the present invention includes combinations of a part of or a whole part of the structures of each of the above-described embodiments.

A part or a whole part of the exemplary embodiments can be depicted as follows. However, it is to be noted that the present invention is not limited only to the structures described below.

(Supplementary Note 1)

A semiconductor laser module which includes: a substrate having a substrate-side electrode; a semiconductor laser chip having a chip-side electrode, and a stripe-form active layer formed in an inner part adjacent to the chip-side electrode; and a solder bump for bonding the substrate-side electrode and the chip-side electrode by being placed only in a part right under the active layer.

(Supplementary Note 2)

The semiconductor laser module as depicted in Supplementary Note 1, wherein: provided that size in a direction orthogonal to an extending direction of the active layer in a surface at which the chip-side electrode and the solder bump are in contact is width, the width of the solder bump is 100 μm or less at maximum.

(Supplementary Note 3)

The semiconductor laser module as depicted in Supplementary Note 1 o 2, wherein: provided that a direction orthogonal to an extending direction of the active layer in a surface at which the chip-side electrode and the solder bump contact is X-axis, size in the X-axis is width, center of the width of the active layer is an origin of the X-axis, a coordinate of the width of the active layer on the X-axis is ±a, and a coordinate of the width of the solder bump on the X-axis is ±b, a following expression applies.

|2a|<|2b|≦100 [μm]

(Supplementary Note 4)

The semiconductor laser module as depicted in any one of Supplementary Notes 1 to 3, wherein at least one of the substrate or the semiconductor laser chip includes a pedestal which sets height of the solder bump corresponding to distance between the substrate-side electrode and the chip-side electrode to a value defined in advance.

(Supplementary Note 5)

The semiconductor laser module as depicted in Supplementary Note 4, wherein: the pedestal is formed on the substrate at positions where both ends of the semiconductor laser chip in a direction orthogonal to an extending direction of the active layer are in contact.

(Supplementary Note 6)

The semiconductor laser module as depicted in any one of Supplementary Notes 1 to 5, wherein the solder bump is in a cylindroid shape, and disposed in such a manner that a major axis of the solder bump comes to be in an extending direction of the active layer.

(Supplementary Note 7)

The semiconductor laser module as depicted in any one of Supplementary Notes 1 to 5, wherein the solder bump is in a round columnar shape.

(Supplementary Note 8)

A method for manufacturing the semiconductor laser module depicted in any one of Supplementary Notes 1 to 3, which includes: placing the solder bump on the substrate-side electrode of the substrate; placing the semiconductor laser chip on the solder bump by facing the chip-side electrode towards the solder bump; and bonding the substrate-side electrode and the chip-side electrode through heating and melting the solder bump.

(Supplementary Note 9)

A method for manufacturing the semiconductor laser module depicted in Supplementary Note 5, which includes: placing the solder bump on the substrate-side electrode of the substrate; placing the semiconductor laser chip on the solder bump and the pedestals by facing the chip-side electrode towards the solder bump; and bonding the substrate-side electrode and the chip-side electrode through heating and melting the solder bump.

(Supplementary Note 10)

A method for manufacturing a semiconductor laser module including a substrate having a substrate-side electrode, a semiconductor laser chip having a chip-side electrode, and a stripe-form active layer formed in an inner part adjacent to the chip-side electrode, and a solder bump for bonding the substrate-side electrode and the chip-side electrode by being placed only in a part right under the active layer, and the method includes: placing the solder bump on the substrate-side electrode of the substrate; placing the semiconductor laser chip on the solder bump by facing the chip-side electrode towards the solder bump; and bonding the substrate-side electrode and the chip-side electrode through heating and melting the solder bump.

(Supplementary Note 11)

A method for manufacturing a semiconductor laser module including a substrate having a substrate-side electrode, a semiconductor laser chip having a chip-side electrode, and a stripe-form active layer formed in an inner part adjacent to the chip-side electrode, a solder bump for bonding the substrate-side electrode and the chip-side electrode by being placed only in a part right under the active layer, and pedestals formed on the substrate at positions where both ends of the semiconductor laser chip in a direction orthogonal to the extending direction of the active layer for setting the height of the solder bump corresponding to the distance between the substrate-side electrode and the chip-side electrode as a value defined in advance, and the method includes: placing the solder bump on the substrate-side electrode of the substrate; placing the semiconductor laser chip on the solder bump and the pedestals by facing the chip-side electrode towards the solder bump; and bonding the substrate-side electrode and the chip-side electrode through heating and melting the solder bump.

(Supplementary Note 12)

The semiconductor laser module as depicted in any one of Supplementary Notes 1 to 7, wherein, when the solder bump is defined as a first solder bump, the semiconductor laser module further includes a second solder bump for bonding the substrate-side electrode and the chip-side electrode by being disposed between the first solder bump and a fringe of the semiconductor laser chip.

(Supplementary Note 13)

The semiconductor laser module as depicted in Supplementary Note 1, wherein: provided that size in a direction orthogonal to an extending direction of the active layer in a surface at which the chip-side electrode and the solder bump are in contact is width, the solder bump includes a main body having the width of 100 μm or less at maximum and a projection part having the width over 100 μm.

### INDUSTRIAL APPLICABILITY

The present invention can be utilized for optical communications such as FTTH, for example.

What is claimed is:

1. A semiconductor laser module, comprising:
a substrate having a substrate-side electrode;
a semiconductor laser chip having a chip-side electrode, and a stripe-form active layer formed in an inner part adjacent to the chip-side electrode; and
a solder bump for bonding the substrate-side electrode and the chip-side electrode by being placed only in a part right under the active layer.

2. The semiconductor laser module as claimed in claim 1, wherein:
provided that size in a direction orthogonal to an extending direction of the active layer in a surface at which the chip-side electrode and the solder bump are in contact is width, the width of the solder bump is 100 μm or less at maximum.

3. The semiconductor laser module as claimed in claim 1, wherein:
provided that a direction orthogonal to an extending direction of the active layer in a surface at which the chip-side electrode and the solder bump contact is X-axis, size in the X-axis is width, center of the width of the active layer is an origin of the X-axis, a coordinate of the width of the active layer on the X-axis is ±a, and a coordinate of the width of the solder bump on the X-axis is ±b, a following expression applies.

|2a|<|2b|≦100 [μm]

4. The semiconductor laser module as claimed in claim 1, wherein
at least one of the substrate or the semiconductor laser chip comprises a pedestal which sets height of the solder bump corresponding to distance between the substrate-side electrode and the chip-side electrode to a value defined in advance.

5. The semiconductor laser module as claimed in claim 4, wherein:
the pedestal is formed on the substrate at positions where both ends of the semiconductor laser chip in a direction orthogonal to an extending direction of the active layer are in contact.

6. The semiconductor laser module as claimed in claim 1, wherein
the solder bump is in a cylindroid shape, and disposed in such a manner that a major axis of the solder bump comes to be in an extending direction of the active layer.

7. The semiconductor laser module as claimed in claim 1, wherein
the solder bump is in a round columnar shape.

8. The semiconductor laser module as claimed in claim 1, wherein, when the solder bump is defined as a first solder bump, the semiconductor laser module further comprises a second solder bump for bonding the substrate-side electrode and the chip-side electrode by being disposed between the first solder bump and a fringe of the semiconductor laser chip.

9. The semiconductor laser module as claimed in claim 1, wherein:
provided that size in a direction orthogonal to an extending direction of the active layer in a surface at which the chip-side electrode and the solder bump are in contact is width, the solder bump includes a main body having the width of 100 μm or less at maximum and a projection part having the width over 100 μm.

10. A method for manufacturing a semiconductor laser module comprising a substrate having a substrate-side electrode,
a semiconductor laser chip having a chip-side electrode, and a stripe-form active layer formed in an inner part adjacent to the chip-side electrode, and
a solder bump for bonding the substrate-side electrode and the chip-side electrode by being placed only in a part right under the active layer, the method comprising:
placing the solder bump on the substrate-side electrode of the substrate;
placing the semiconductor laser chip on the solder bump by facing the chip-side electrode towards the solder bump; and
bonding the substrate-side electrode and the chip-side electrode through heating and melting the solder bump.
